(19) United States
(12) Patent Application Publication
(10) Pub. No.: US 2007/0016711 A1
(43) Pub. Date: Jan. 18, 2007

(54) Interfacing structure for multiple graphic

(75) Inventor: Kung-Chung Yang, Chung Ho City (TW)

Correspondence Address: LEONG C LEI, PMB # 1008, 1867 YGNACIO VALLEY ROAD, WALNUT CREEK, CA, 94598, US

(73) Assignee: Jet Way Information Co., Ltd.

(21) Appl. No.: 11/179,588

(22) Filed: Jul. 13, 2005

(51) Int. Cl. H05K 7/10

(52) U.S. Cl. 710/301

(57) ABSTRACT

An interfacing structure for a computer motherboard is provided herein, which is specifically designed to simply the installation of multiple graphic adaptors compliant with Scalable Link Interface (SLI) standards. The interfacing structure contains at least three PCI Express x16 slots, two of which are for the installation of the SLI-compliant graphic adaptors, and the remaining one is for the installation of a normal graphic adaptor. Within the motherboard's wiring layout, each of the two SLI slots connects to eight of the sixteen channels of the PCI Express x16 interface respectively, while the normal slot connects to all sixteen channels.

### BACKGROUND OF THE INVENTION

(a) Technical Field of the Invention

The present invention generally relates to the input/output interface of computer motherboards, and more particularly to an input/output interfacing structure for simplifying the installation of multiple graphic adaptors on the motherboard.

(b) Description of the Prior Art

PCI Express (referred to as PCIe hereinafter) is an advanced computer input/output (I/O) interfacing standard for originally proposed by Intel@. A PCIe interface could be one of several formats such as PCIe x1, PCIe x2, PCIe x4, PCIe x8, PCIe x16, where the numeral stands for the number of dual-directional communication channels supported by the PCIe interface. For example, PCIe x1 is composed of a single channel; PCIe x2 is composed of two channels, and so on. Each channel is capable of providing data input and output transmission speed up to 500 MB/sec. For motherboards adopting this new I/O interface standard, a single PCIe x16 interface is usually provided to replace the conventional, slower VGA AGP 8X interface.

On the other hand, nVIDIA®, a graphic chipset company headquartered in the United States, also proposes a Scalable Link (SLI) standard based on the PCIe interface. According to the SLI standard, two SLI-compliant graphic adaptors could be plugged into two slots on the motherboard sharing a single PCIe x16 interface. The two slots are referred to as PCIe x16 slots hereinafter. After the two adaptors are series-connected by a bridge connector, they could work in collaboration to drive a single high-end screen for very computational intensive graphic tasks such as three-dimensional modeling and rendering. Similar to dual-processor architecture, the SLI standard divides and dispatches the required graphic computation to the graphic processors on the two SLI-compliant adaptors and, then, combines the results from the two adaptors into a single frame. An extremely high graphic performance is thereby achieved.

However, a SLI-compliant motherboard is not always equipped with the SLI-compliant graphic adaptors. It is very possible that a user would just like to use a single normal PCle x16 graphic adaptor for the graphic display. To maintain such a flexibility, motherboard manufacturers conventionally adopts an interfacing structure as shown in FIG. 1. For simplicity sake, the rest of the motherboard 100 of FIG. 1 is omitted. SLI-compliant graphic adaptors are usually of a significant thickness due to their large heat dissipation modules, the two PCIe x16 slots 110 and 120 (referred to as master and slave slots respectively hereinafter) are commonly separated apart for an appropriate distance. Within this gap, a switch module 130 is usually configured by the motherboard manufacturers, which contains a jack 132 on the motherboard 100, and a circuit board 134. The circuit board 134 could be plugged into the jack 132 using one of its two sides (referred to as (A) side and (B) side respectively hereinafter). When (A) side is plugged into the jack 132, all sixteen channels of the PCIe x16 interface is connected to the master slot 110 and the slave slot 120 is therefore not functioning. This configuration is used when a single PCIe x16 graphic adaptor is to be installed on the motherboard 100 (referred to as normal mode hereinafter). On the other hand, when (B) side is plugged into the jack 132, each of the two slots 110 and 120 connects to eight of the sixteen channels respectively. This configuration is used when a two SLI-compliant PCIe x16 graphic adaptor are to be installed on the motherboard 100 (referred to as SLI mode hereinafter).

Such a mechanism is not quite friendly to the user. If a user has only one PCIe x16 graphic adaptor (or just like to use the normal mode), the user has to located the master slot, plug the adaptor into the master slot, and insert the correct side (side (A)) of the circuit board 134 into the jack 132. If the wrong side is inserted into the jack 132, the I/O bandwidth to the graphic adaptor is cut down in half as only eight channels of the PCIe x16 interface is available. If the user has two SLI-compliant adaptors, even though the distinction of the master and slave slots is of no relevance, the user still has to insert the right side (side (B)) into the jack 132; otherwise co-processing SLI mode would not function.

### SUMMARY OF THE INVENTION

As the installation of graphic adaptors on a conventional SLI-compliant motherboard is troublesome and prone to human error, a major objective of the present invention is to provide an interfacing structure so that the graphic adaptors could be installed intuitively and correctly with ease.

The interfacing structure of the present invention is an integral part of a SLI-compliant motherboard. The interfacing structure contains at least three PCI Express x16 slots, two of which are for the installation of the SLI-compliant graphic adaptors under the SLI mode, and the remaining one is for the installation of a normal graphic adaptor under the normal node. Within the motherboard's wiring layout, each of the two SLI slots connects to eight of the sixteen channels of the PCI Express x16 interface respectively, while the normal slot connects to all sixteen channels.

The three slots are marked with visual clues so that a user could identify and distinguish them easily. In one embodiment of the present invention, the two SLI slots have green jacks while the normal slot has a yellow jack. In terms of location, the normal slot is arranged in the gap between the two SLI slots, which is where the conventional switch module is located. As such, a motherboard adopting the present invention does not require more motherboard real estate than a conventional motherboard or need to sacrifice other components on the motherboard.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic diagram showing the conventional interfacing structure for SLI-compliant graphic adaptors.

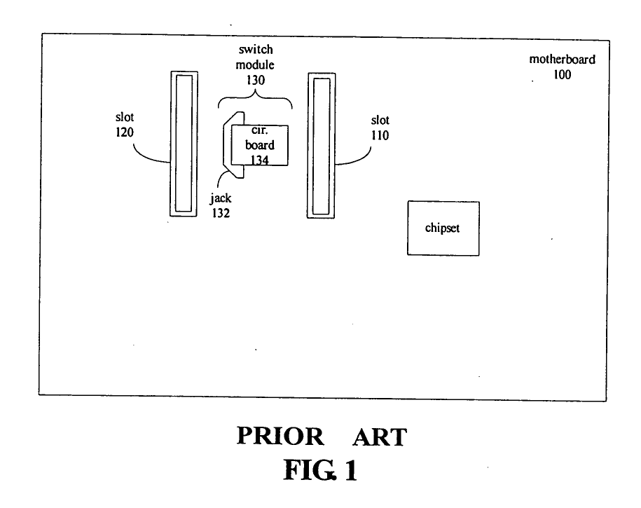

FIG. 2 is a schematic diagram showing the interfacing structure according to an embodiment of the present invention.

FIG. 3 is a schematic diagram showing the wiring layout of an interfacing structure according to an embodiment of the present invention.

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

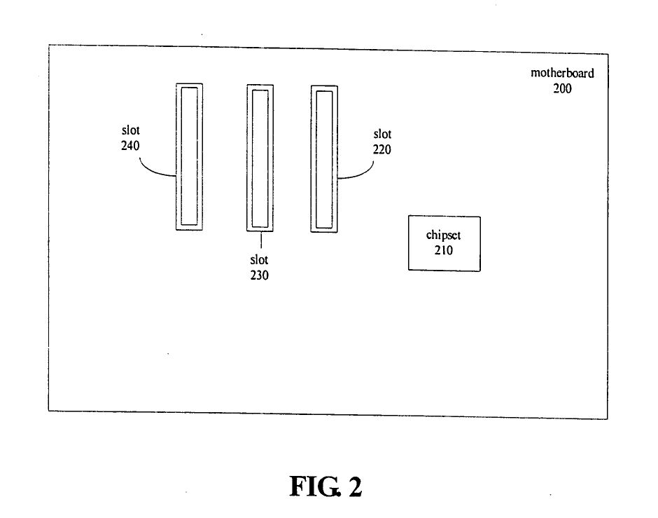

FIG. 2 is a schematic diagram showing the interfacing structure according to an embodiment of the present invention. The interfacing structure is an integral part of a SLI-compliant motherboard 200, which means that the motherboard 200 is configured with an appropriate chipset 210, such as the nForce4™ chipset by NVIDIA and, therefore, is capable of supporting at least a PCIe x16 interface and at least two PCle x16 slots. As to the other components of the motherboard 200, they are of no relevance to the present invention and therefore are omitted in the accompanied drawings and the following text.

The interfacing structure contains at least three PCIe x16 slots 220, 230, and 230. Among them, the slots 220 and 240 are dedicated for the installation of the two SLI-compliant graphic adaptors under the SLI mode. The slot 230, on the other hand, is dedicated to the installation of a single PCIe x16 graphic adaptor under the normal mode. As the SLI-compliant graphic adaptors are rather thick from their bulky on-board heat dissipation modules, the slots 220 and 240 are spaced apart for an appropriate distance, with the slot 230 arranged between them. Please note that there are other alternatives for arranging the three slots. However, the foregoing arrangement as shown in FIG. 2 is the most space-saving one. Additionally, the slot 230 is positioned where the switch module 130 of a conventional motherboard 100 is located. Therefore, the motherboard 200 does not require any more motherboard real estate than what is required by the conventional motherboard 100. The motherboard 200 is not required to sacrifice other components either.

To avoid confusion when a user is installing graphic adaptors, the three slots are marked with visual clues. In the present embodiment, the SLI slots 220 and 240 use green jacks while the normal slot 230 uses a yellow jack. In alternative embodiments, other types of visual clues could be adopted such as different sets of color or text markings.

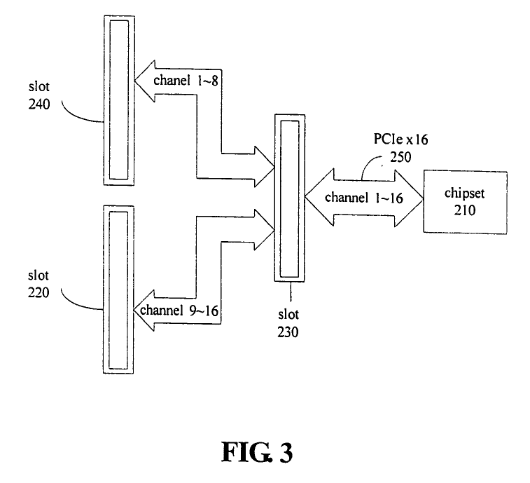

As shown in FIG. 3, the three slots 220, 230, and 240 share a single PCIe x16 interface 250 from the chipset 210. The SLI slots 220 and 240 connect to the first and the last eight channels of the sixteen channels of the PCIe x16 interface 250 respectively, while the normal slot 230 connects to all sixteen channels. With such a wiring layout, the present invention therefore could totally avoid the use of a switch module.

If the user has only one PCIe x16 graphic adaptor, the user could easily identify the normal slot 230 and plug in the graphic adaptor correctly. The user does not need to care which one is the master slot, has no switch module to adjust, not worry whether there is only half of the bandwidth available. Similarly, if the user has two SLI-compliant PCIe x16 graphic adaptors, the user could simply plug the two adaptors to the two slots 220 and 240, and there is no need to adjust any switch module.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A graphic adaptor interfacing structure for a SLI-compliant computer motherboards, said motherboard having an appropriate chipset supporting at least a PCIe x 16 interface, said interfacing structure comprising:
two PCIe x16 slots for the installation of two SLI-compliant PCIe x16 graphic adaptors for operation under the SLI mode; and
one PCIe x16 slot for the installation of a PCIe x16 graphic adaptor for operation under the normal mode;
wherein said normal mode slot connects to all sixteen channels of said PCIe x16 interface, and said two SLI mode slots connect to the first eight channels and the last eight channels of said PCIe x16 interface.

2. The graphic adaptor interfacing structure according to claim 1, wherein said SLI slots and said normal slot are marked with visual clues so that a user could distinguish between them visually.

3. The graphic adaptor interfacing structure according to claim 2, wherein said visuals clues are based on colors.

4. The graphic adaptor interfacing structure according to claim 1, wherein said SLI slots are spaced apart for an appropriate distance while said normal slot is positioned between said SLI slots.
